(19) United States
(12) Patent Application Publication
(10) Pub. No.: US 2021/0088289 A1
(43) Pub. Date: Mar. 25, 2021

(54) VAPOR CHAMBER

(71) Applicant: DELTA ELECTRONICS, INC., Taoyuan City (TW)

(72) Inventors: Shih-Lin HUANG, Taoyuan City (TW); Chiu-Kung CHEN, Taoyuan City (TW); Ting-Yuan WU, Taoyuan City (TW)

(21) Appl. No.: 17/111,077

(22) Filed: Dec. 3, 2020

Related U.S. Application Data
(63) Continuation of application No. 15/699,726, filed on Sep. 8, 2017.

(30) Foreign Application Priority Data
Jan. 18, 2017 (CN) 201710037900.7

(51) Int. Cl. F28D 15/04; H01L 23/427

(52) U.S. Cl. CPC F28D 15/046; F28D 15/0233; H01L 23/427

(57) ABSTRACT

A vapor chamber is provided. The vapor chamber is adapted to be thermally connected to an electronic element. The vapor chamber includes a first member and a second member. The first member has a first heat transfer coefficient. The first member is connected to the electronic element. The second member has a second heat transfer coefficient. The second member is combined with the first member. The first member is located between the second member and the electronic element. The first heat transfer coefficient is greater than the second heat transfer coefficient.

### CROSS REFERENCE TO RELATED APPLICATIONS

This application is a Continuation of pending U.S. patent application Ser. No. 15/699,726, filed Sep. 8, 2017 and entitled “vapor chamber”, which claims priority of China Patent Application No. 201710037900.7, filed on Jan. 18, 2017, the entirety of which is incorporated by reference herein.

### BACKGROUND OF THE INVENTION

### Field of the Invention

The present invention relates to a vapor chamber, and in particular to a vapor chamber which is connected to an electronic element and that removes heat from the electronic element.

### Description of the Related Art

Conventional vapor chambers are made of copper or copper alloy, and include a heat source contacting side (lower member) and a heat source non-contacting side (upper member). The lower member and the upper member have connection surfaces which are combined in a diffusion bonding process to seal the periphery of the vapor chamber. However, the specific gravity of the copper or copper alloy is high (˜8.9 g/cm³), and the strength of the copper or copper alloy decreases after a high-temperature process. A conventional vapor chamber made of copper or copper alloy therefore is thick, heavy, and low in strength.

### BRIEF SUMMARY OF THE INVENTION

In one embodiment, a vapor chamber is provided. The vapor chamber is adapted to be thermally connected to an electronic element. The vapor chamber includes a first member and a second member. The first member has a first heat transfer coefficient. The first member is connected to the electronic element. The second member has a second heat transfer coefficient. The second member is combined with the first member. The first member is located between the second member and the electronic element. The first heat transfer coefficient is greater than the second heat transfer coefficient.

In one embodiment, the first member is combined with the second member by welding.

In one embodiment, the first member is combined with the second member by laser welding, high-frequency welding, friction welding, or argon arc welding.

In one embodiment, materials of the first and second members are selected from a group consisting of copper, copper alloy, titanium, titanium alloy, aluminum, aluminum alloy, stainless steel, ceramic, graphite and polymeric fiber.

In one embodiment, the flatness of the first member is greater than the flatness of the second member.

In one embodiment, a vapor chamber is provided. The vapor chamber is adapted to be thermally connected to an electronic element. The vapor chamber includes a first member and a second member. The first member has a first electronic shielding coefficient, wherein the first member is connected to the electronic element. The second member has a second electronic shielding coefficient, wherein the second member is combined with the first member, the first member is located between the second member and the electronic element, and the second electronic shielding coefficient is greater than the first electronic shielding coefficient.

In one embodiment, the first member is combined with the second member by welding.

In one embodiment, a plurality of capillary structures are formed on an inner surface of the second member, and the capillary structures extend toward the first member.

In one embodiment, the electronic element is disposed on a circuit board, a holding unit is disposed on the circuit board and abuts and restricts the second member, and the holding unit is made of an electrically conductive material.

In one embodiment, a vapor chamber is provided. The vapor chamber is adapted to be thermally connected to an electronic element. The vapor chamber includes a first member, a second member and a media layer. The first member is connected to the electronic element. The second member is combined with the first member. The media layer is sandwiched between the first and second members, wherein the melting point of the first member and that of the second member are greater than that of the media layer.

In one embodiment, the hardness of the first member and that of the second member are greater than that of the media layer.

In one embodiment, the strength of the first member and that of the second member are greater than that of the media layer.

In one embodiment, the media layer is formed between the first and second members by plating or sputtering.

In one embodiment, the media layer is formed between the first and second members by hot pressing.

In one embodiment, the media layer has no adhesion in room temperature.

In one embodiment, the melting point of the first member and that of the second member are greater than 500° C.

In one embodiment, the wall thickness of the first member and that of the second member are less than 0.2 mm.

In one embodiment, materials of the first and second members are selected from a group consisting of copper, copper alloy, titanium, titanium alloy, aluminum, aluminum alloy, stainless steel, ceramic, graphite and polymeric fiber.

In one embodiment, the material of the media layer is selected from a group consisting of copper, copper alloy, titanium, titanium alloy, aluminum, aluminum alloy and stainless steel.

In one embodiment, the vapor chamber further comprises a porous material, and the porous material is disposed in a chamber formed by the first and second members.

The vapor chamber of the embodiment of the invention has advantages such as being thin and lightweight and having high strength and high heat-dissipation efficiency.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is an exploded view of a vapor chamber of an embodiment of the invention;

FIG. 2 shows the assembled vapor chamber of the embodiment of FIG. 1;

FIG. 3 shows a vapor chamber of another embodiment of the invention;

FIG. 4A is an exploded view of a vapor chamber of another embodiment of the invention; and

FIG. 4B shows the assembled vapor chamber of the embodiment of FIG. 4A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

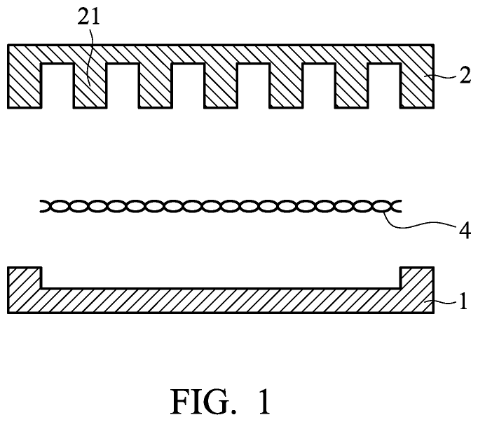

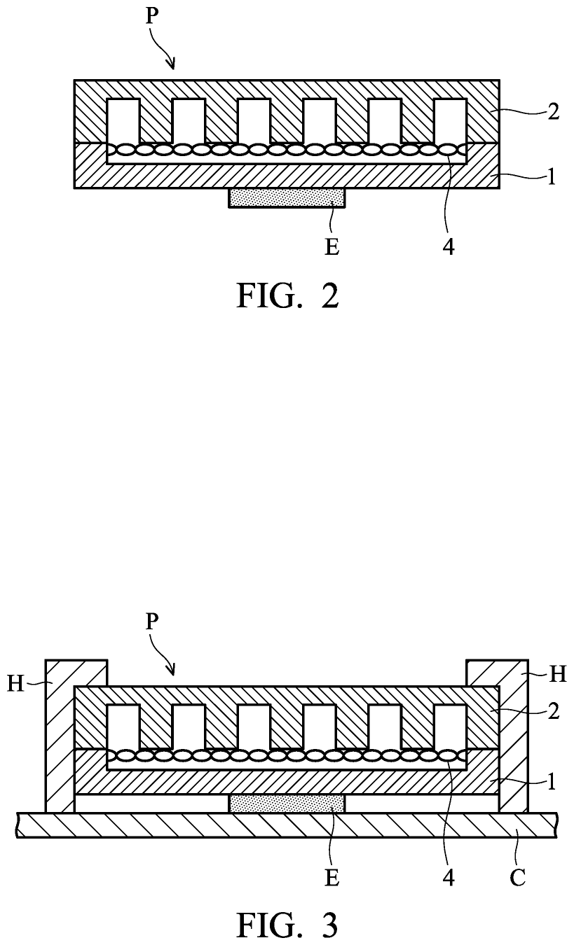

FIGS. 1 and 2 show a vapor chamber P of an embodiment of the invention. The vapor chamber P is adapted to be thermally connected to an electronic element E. In this embodiment, the vapor chamber P includes a first member 1 and a second member 2. The first member 1 has a first heat transfer coefficient. The first member 1 is connected to the electronic element E. The second member 2 has a second heat transfer coefficient. The second member 2 is combined with the first member 1. The first member 1 is located between the second member 2 and the electronic element E. The first heat transfer coefficient is greater than the second heat transfer coefficient. The first member 1 provides a heat dissipation function with the first heat transfer coefficient (the higher heat transfer coefficient). The second member 2 has a decreased surface temperature, and is prevented from scalding the user.

In one embodiment, the first strength of the first member 1 is greater than the second strength of the second member 2. The first member 1 provides a support function with the first strength (the higher strength).

With reference to FIGS. 1 and 2, in one embodiment, the first member 1 is combined with the second member 2 by welding. For example, the first member 1 is combined with the second member 2 by laser welding, high-frequency welding, friction welding, or argon arc welding. In one embodiment, materials of the first and second members 1, 2 are selected from a group consisting of copper, copper alloy, titanium, titanium alloy, aluminum, aluminum alloy, stainless steel, ceramic, graphite and polymeric fiber.

In one embodiment, the flatness of the first member 1 is greater than that of the second member 2. Therefore, the first member 1 can come into sufficiently close contact with the electronic element E to transmit heat. The second member 2 provides a heat dissipation function that is much improved due to the uneven surface.

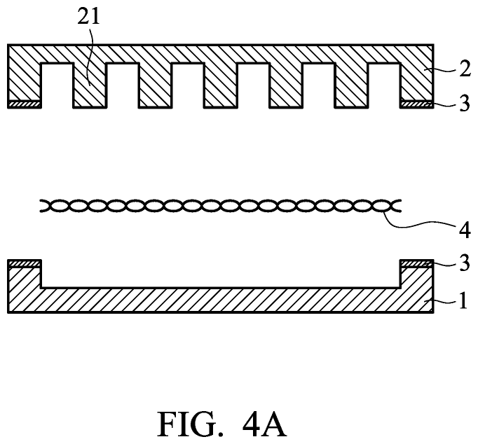

With reference to FIGS. 1 and 3, in a second embodiment, a vapor chamber P is provided. The vapor chamber P is adapted to be thermally connected to an electronic element E. The vapor chamber P is comprised by a first member 1 and a second member 2. The first member 1 has a first electronic shielding coefficient, wherein the first member 1 is connected to the electronic element E. The second member 2 has a second electronic shielding coefficient. The second member 2 is combined with the first member 1. The first member 1 is located between the second member 2 and the electronic element E. The second electronic shielding coefficient is greater than the first electronic shielding coefficient. Similar to the first embodiment, the first member 1 is combined with the second member 2 by welding. The materials of the first member 1 and the second member 2 are selected from a group consisting of copper, copper alloy, titanium, titanium alloy, aluminum, aluminum alloy, stainless steel, ceramic, graphite and polymeric fiber.

In the second embodiment, the first member 1 has a first heat transfer coefficient, and the second member 1 has a second heat transfer coefficient. The first heat transfer coefficient is greater than the second heat transfer coefficient. The first member 1 provides a heat dissipation function with the first heat transfer coefficient (the higher heat transfer coefficient). The second member 2 provides an electronic shielding function with the second electronic shielding coefficient (the higher electronic shielding coefficient). Similar to the first embodiment, the flatness of the first member 1 is greater than thatof the second member 2. Therefore, the first member 1 can come into sufficiently close contact with the electronic element E to transmit heat. The second member 2 provides better heat dissipation than the uneven surface. In a modified example, a surface processing is applied to the surface of the vapor chamber P to increase the heat dissipation area and the heat dissipation efficiency.

With reference to FIGS. 1 and 3, in one embodiment, a plurality of capillary structures 21 are formed on an inner surface of the second member 2, and the capillary structures 21 extend toward the first member 1. The fluid inside the vapor chamber P exchanges heat with the capillary structures 21 to improve the heat dissipation efficiency.

With reference to FIG. 3, in one embodiment, the electronic element E is disposed on a circuit board C. A holding unit H is disposed on the circuit board C and abuts and restricts the second member 2. The holding unit H is made of an electrically conductive material. In one embodiment, the holding unit H is grounded to provide an improved electronic shielding function.

With reference to FIG. 1, in one embodiment, the vapor chamber P further comprises a porous material 4, and the porous material 4 is disposed in a chamber formed by the first and second members 1, 2. The porous material 4 can be fiber or metal net.

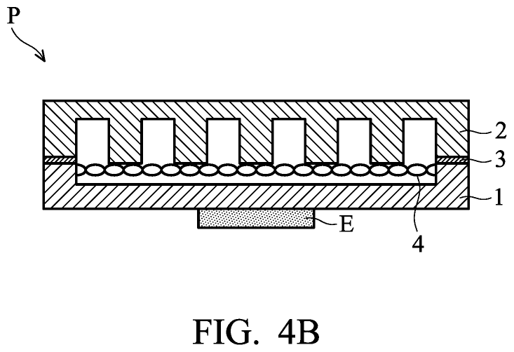

With reference to FIGS. 4A and 4B, in a third embodiment, a vapor chamber P is provided. The vapor chamber P is adapted to be thermally connected to an electronic element E. The vapor chamber P includes a first member 1, a second member 2 and a media layer 3. The first member 1 is connected to the electronic element E. The second member 2 is combined with the first member 1. The media layer 3 is sandwiched between the first and second members 1, 2, wherein the melting point of the first member 1 and that of the second member 2 are greater than that of the media layer 3.

In one embodiment, the hardness of the first member 1 and that of the second member 2 are greater than that of the media layer 3. The media layer 3 is formed between the first and second members 1, 2 by plating or sputtering. In one embodiment, the media layer 3 can also be formed between the first and second members 1, 2 by hot pressing.

In one embodiment, the media layer 3 has no adhesion in room temperature.

The melting point of the first member 1 and the that of the second member 2 are greater than 500° C. The melting point of the media layer 3 is greater than the operation temperature of the vapor chamber, but less than the melting point of the first member 1 and that of the second member 2. In one embodiment, the wall thickness of the first member 1 and that of the second member 2 are less than 0.2 mm.

In one embodiment, the material of the media layer 3 is selected from a group consisting of copper, copper alloy, titanium, titanium alloy, aluminum, aluminum alloy and stainless steel. In the third embodiment, the media layer 3 is preformed between the first and second members 1, 2 by plating or sputtering to perform diffusion bonding between the first and second members, which are made of the same material or two different materials, and to seal the periphery of the vapor chamber. The vapor chamber of the embodiment of the invention has the advantages of being thin and lightweight, and having high strength and high heat dissipation efficiency.

With reference to FIGS. 4A and 4B, in one embodiment, the vapor chamber P further comprises a porous material 4, and the porous material 4 is disposed in a chamber formed by the first and second members 1, 2. The porous material 4 can be fiber or metal net.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A vapor chamber, adapted to be thermally connected to an electronic element, comprising:
a first member, made by a first material, wherein the first material has a first thermal conductivity, and the first member is connected to the electronic element;
a second member, made by a second material, wherein the second material has a second thermal conductivity, the second member is combined with the first member, the first member is located between the second member and the electronic element, and the first thermal conductivity is greater than the second thermal conductivity, wherein the second member is combined with the first member to form a closed chamber;
a porous material, wherein the porous material is disposed in the closed chamber,
wherein materials of the second member are selected from a group consisting of ceramic, graphite and polymeric fiber.

2. The vapor chamber as claimed in claim 1, wherein the first member is combined with the second member by laser welding, high-frequency welding, friction welding, or argon arc welding.

3. The vapor chamber as claimed in claim 1, wherein a flatness of the first member is greater than that of the second member.

4. The vapor chamber as claimed in claim 1, wherein a plurality of capillary structures are formed on an inner surface of the second member, and the capillary structures extend toward the first member.

5. The vapor chamber as claimed in claim 4, wherein the porous material is located between the capillary structures and a bottom inner surface of the first member.

6. The vapor chamber as claimed in claim 5, wherein the porous material is clipped by the capillary structures and the first member.

7. The vapor chamber as claimed in claim 5, wherein each of the capillary structures has a free end, and the free end contacts the porous material.

8. The vapor chamber as claimed in claim 7, wherein the first member is seamless formed, and the second member is seamless formed.

9. The vapor chamber as claimed in claim 8, further comprising a media layer, wherein the media layer is sandwiched between the first member and second member.

10. The vapor chamber as claimed in claim 9, wherein a first vertical distance is formed between the media layer and the electronic element, a second vertical distance is formed between the porous material and the electronic element, and the first vertical distance is longer than the second vertical distance.
